(19) United States
(12) Patent Application Publication
(10) Pub. No.: US 2021/0391152 A1
(43) Pub. Date: Dec. 16, 2021

(54) STAGE, SUBSTRATE PROCESSING APPARATUS, AND SUBSTRATE PROCESSING METHOD

(71) Applicant: Tokyo Electron Limited, Tokyo (JP)

(72) Inventor: Shingo KOIWA, Miyagi (JP)

(21) Appl. No.: 17/342,809

(22) Filed: Jun. 9, 2021

(30) Foreign Application Priority Data
Jun. 10, 2020 (JP) 2020-101049

(51) Int. Cl. H01J 37/32; C23C 16/458; C23C 16/50

(52) U.S. Cl. CPC H01J 37/32715; H01J 37/3244; H01L 21/67069; C23C 16/50; C23C 16/4586

(57) ABSTRACT

A substrate support includes: an electrostatic chuck including a substrate support surface on which the substrate is supported; a base configured to support the electrostatic chuck; and an absorption member arranged between the electrostatic chuck and the base and including an outer edge portion fastened to the base via a fastener, wherein, between the electrostatic chuck and the absorption member, a connection region, in which the electrostatic chuck and the absorption member are interconnected in a central portion of the electrostatic chuck, and a separation region, in which the electrostatic chuck and the absorption member are spaced apart from each other on an outer-edge side of the connection region, are formed.

### CROSS-REFERENCE TO RELATED APPLICATION

This application is based upon and claims the benefit of priority from Japanese Patent Application No. 2020-101049, filed on Jun. 10, 2020, the entire contents of which are incorporated herein by reference.

### TECHNICAL FIELD

The present disclosure relates to a stage, a substrate processing apparatus, and a substrate processing method.

### BACKGROUND

Patent Document 1 discloses a plasma processing apparatus which includes a stage on which a substrate is placed, an annular member arranged so as to surround the substrate placed on the stage, and a voltage supply device configured to supply radio-frequency power to the stage, wherein plasma processing is performed on the substrate within an accommodation chamber. In addition, the plasma processing apparatus disclosed in Patent Document 1 further includes an observation device configured to optically observe the distribution of plasma, a voltage application device configured to apply a DC voltage to the annular member, and a controller configured to set a value of the DC voltage to be applied based on the observed distribution of plasma.

### PRIOR ART DOCUMENT

### Patent Document

Patent Document 1: Japanese Laid-Open Patent Publication No. 2008-227063

### SUMMARY

According to one embodiment of the present disclosure, a substrate support includes: an electrostatic chuck including a substrate support surface on which the substrate is supported; a base configured to support the electrostatic chuck; and an absorption member arranged between the electrostatic chuck and the base and including an outer edge portion fastened to the base via a fastener, wherein, between the electrostatic chuck and the absorption member, a connection region, in which the electrostatic chuck and the absorption member are interconnected in a central portion of the electrostatic chuck, and a separation region, in which the electrostatic chuck and the absorption member are spaced apart from each other on an outer-edge side of the connection region, are formed.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is an explanatory view illustrating a state in which a convex deformation occurs on a conventional stage.

FIG. 2 is a vertical cross-sectional view schematically illustrating an outline of a configuration of a plasma processing system according to an embodiment.

FIG. 3 is a vertical cross-sectional view schematically illustrating an outline of a configuration of a stage according to an embodiment.

FIG. 4 is an explanatory view illustrating a state in which a convex deformation occurs on the stage according to the embodiment.

FIG. 5 is a vertical cross-sectional view schematically illustrating a modification of the stage according to the embodiment.

FIG. 6 is a vertical cross-sectional view schematically illustrating a modification of the stage according to the embodiment.

FIG. 7 is a vertical cross-sectional view schematically illustrating a modification of the stage according to the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacturing process, a plasma processing apparatus generates plasma by exciting a processing gas and processes a semiconductor substrate (hereinafter, referred to as a “substrate”) placed on a stage using the plasma. The stage on which the substrate is placed is provided with an electrostatic chuck configured to attract and hold a substrate on a placement surface thereof by virtue of, for example, Coulomb force.

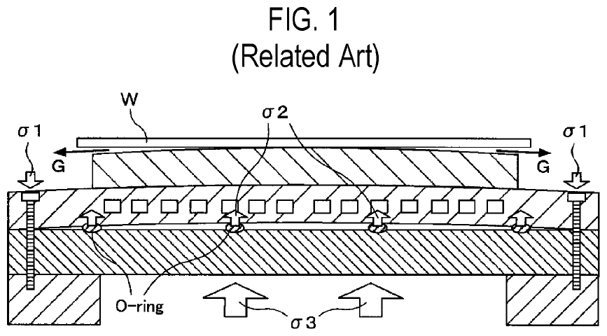

In a structure of an electrostatic chuck provided in an existing stage such as that disclosed in Patent Document 1, as illustrated in FIG. 1, there is a concern that the placement surface of the electrostatic chuck may be deformed into a convex shape due to the influence of, for example, stress 61 acting due to screw fastening, the pushing force 62 acting by an O-ring, and the atmospheric pressure 63 acting due to the pressure difference between the atmospheric space and the processing space. It is difficult to control the convex deformation of the placement surface to be constant due to the influence of, for example, tolerance variation between components and thermal expansion. As a result, there is a risk that it may become difficult to make the placement surface and a substrate W be in uniform contact with each other on the entire surface. When it is impossible to make the placement surface and the substrate W be in uniform contact with each other in this way, there is a concern that the in-plane uniformity of temperature of the substrate in plasma processing may be deteriorated and the amount of leakage of a heat transfer gas G (the backside gas) may increase. That is, there is a risk that it may be impossible to appropriately perform the plasma processing.

Conventionally, as a method for alleviating or solving such problems, it has been proposed, for example, to grind in advance the placement surface of the electrostatic chuck so as to process the placement surface into a concave shape, or to improve the attraction followability of the substrate with respect to the placement surface by increasing the attraction voltage. However, in these conventional methods, there are problems in that a withstand voltage margin when RF is applied to the electrostatic chuck is lowered, and in that the flatness of the placement surface changes due to the tolerance between components and the variation of screw fastening torque. That is, there was room for improvement in the stage having the structure of the conventional electrostatic chuck.

A technique according to the present disclosure was been made in view of the above-mentioned circumstances, and appropriately suppresses, in a stage provided with a substrate placement surface, deterioration of the flatness of the placement surface. Hereinafter, a plasma processing system as a substrate processing apparatus including a stage according to an embodiment will be described with reference to the drawings. In this specification and the accompanying drawings, elements having substantially the same functional configurations will be denoted by the same reference numerals and redundant descriptions thereof will be omitted.

### <Plasma Processing System>

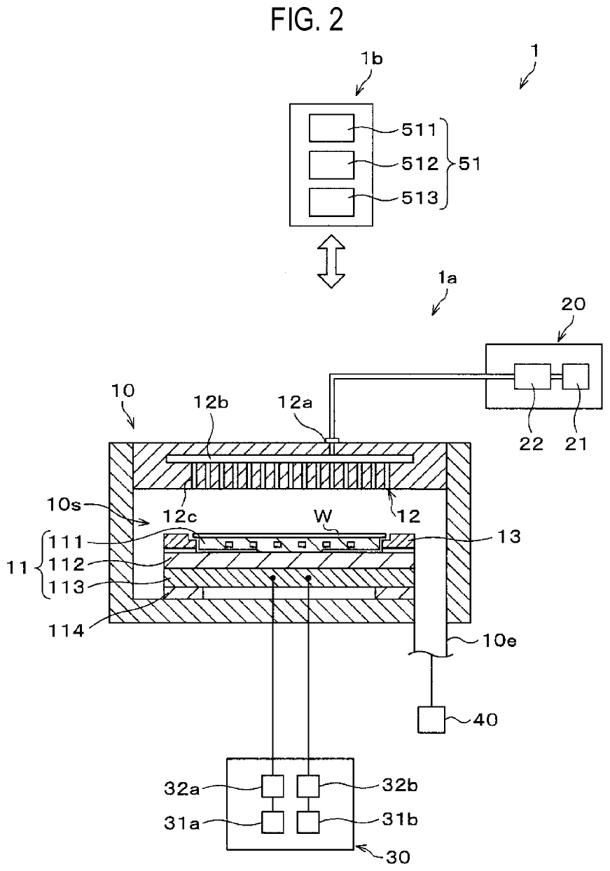

First, a plasma processing system as a substrate processing system according to an embodiment will be described. FIG. 2 is a vertical cross-sectional view illustrating an outline of a configuration of a plasma processing system 1. The plasma processing system 1 includes a capacitively coupled plasma processing apparatus, and performs plasma processing such as etching, film formation, and diffusion on a substrate W to be processed.

In an embodiment, the plasma processing system 1 includes a plasma processing apparatus 1a and a controller 1b. The plasma processing apparatus 1a includes a plasma processing chamber 10, a gas supply part 20, a radio-frequency (RF) power supply 30, and an exhaust system 40. In addition, the plasma processing apparatus 1a includes a stage 11 used as a substrate support and an upper electrode shower head 12 according to the present embodiment. The stage 11 is arranged in a lower region of a plasma processing space 10s within the plasma processing chamber 10. The upper electrode shower head 12 is located above the stage 11, and may function as a portion of the ceiling of the plasma processing chamber 10.

The stage 11 includes an electrostatic chuck 111 having a substrate support surface for the substrate W, an absorption plate 112 configured to absorb a convex deformation generated on the stage 11, and a support plate 113 configured to support the electrostatic chuck 111 through the absorption plate 112. The stage 11 is fixed to the bottom surface of the plasma processing chamber 10 through a placement base 114. A detailed configuration of the stage 11 will be described later.

In addition, around the substrate support surface of the electrostatic chuck 111, an edge ring 13 (also referred to as a “focus ring”) formed in an annular shape is provided so as to surround the substrate support surface in a plan view. An edge ring 13 is provided in order to improve the uniformity of plasma processing. The edge ring 13 is made of a material appropriately selected depending on the plasma processing to be executed, and may be made of, for example, silicon or quartz.

The upper electrode shower head 12 is configured to supply one or more processing gases from the gas supply part 20 to the plasma processing space 10s. In an embodiment, the upper electrode shower head 12 has a gas inlet 12a, a gas diffusion chamber 12b, and a plurality of gas outlets 12c. The gas inlet 12a is in fluid communication with the gas supply part 20 and the gas diffusion chamber 12b. The plurality of gas outlets 12c are in fluid communication with the gas diffusion chamber 12b and the plasma processing space 10s. In an embodiment, the upper electrode shower head 12 is configured to supply one or more processing gases from the gas inlet 12a to the plasma processing space 10s via the gas diffusion chamber 12b and the plurality of gas outlets 12c.

The gas supply part 20 may include one or more gas sources 21 and one or more flow controllers 22. In an embodiment, the gas supply part 20 is configured to supply one or more processing gases from the respective gas sources 21 to the gas inlet 12a via the respective flow controllers 22. Each of the flow controllers 22 may include, for example, a mass flow controller or a pressure-controlled flow controller. In addition, the gas supply part 20 may include one or more flow rate modulation devices configured to modulate or pulse flow rates of one or more processing gases.

The RF power supply 30 is configured to supply RF power (e.g., one or more RF signals) to one or more electrodes, such as a support plate 113 serving as a lower electrode, the upper electrode shower head 12, or both the support plate 113 and the upper electrode shower head 12. As a result, plasma is generated from the one or more processing gases supplied to the plasma processing space 10s. Therefore, the RF power supply 30 is capable of functioning as at least portion of a plasma generation part configured to generate plasma from one or more processing gases in the plasma processing chamber 10. In an embodiment, the RF power supply 30 includes two RF generators 31a and 31b and two matching circuits 32a and 32b. In an embodiment, the RF power supply 30 is configured to supply a first RF signal from a first RF generator 31a to the support plate 113 via a first matching circuit 32a. For example, the first RF signal may have a frequency in the range of 27 MHz to 100 MHz.

In an embodiment, the RF power supply 30 is configured to supply a second RF signal from a second RF generator 31b to the support plate 113 via a second matching circuit 32b. For example, the second RF signal may have a frequency in the range of 400 kHz to 13.56 MHz. In some embodiments, a direct current (DC) pulse generator may be used instead of the second RF generator 31b.

In addition, although not illustrated, other embodiments may be considered in the present disclosure. For example, in an alternative embodiment, the RF power supply 30 may be configured to supply a first RF signal from an RF generator to the support plate 113, to supply a second RF signal from another RF generator to the support plate 113, and to supply a third RF signal from still another RF generator to the support plate 113. In addition, in other alternative embodiments, a DC voltage may be applied to the upper electrode shower head 12.

Furthermore, in various embodiments, the amplitudes of one or more RF signals (i.e., the first RF signal, the second RF signal, and the like) may be pulsed or modulated. Such an amplitude modulation may include pulsing RF signal amplitudes between ON and OFF states, or between two or more different ON states.

The exhaust system 40 may be connected to, for example, an exhaust port 10e provided in the bottom portion of the plasma processing chamber 10. The exhaust system 40 may include a pressure valve and a vacuum pump. The vacuum pump may include a turbo molecular pump, a roughing pump, or a combination thereof.

In an embodiment, the controller 1b processes computer-executable instructions that cause the plasma processing apparatus 1a to perform various steps described in the present disclosure. The controller 1b may be configured to control each element of the plasma processing apparatus 1a to perform various steps described herein. In an embodiment, a portion or all of the controller 1b may be included in the plasma processing apparatus 1a. The controller 1b may include, for example, a computer 51. The computer 51 may include, for example, a processor (central processing unit (CPU)) 511, a storage part 512, and a communication interface 513. The processor 511 may be configured to perform various control operations based on a program stored in the storage part 512. The storage part 512 may include a random access memory (RAM), a read only memory (ROM), a hard disk drive (HDD), a solid state drive (SSD), or a combination thereof. The communication interface 513 may communicate with the plasma processing apparatus 1a via a communication line such as a local area network (LAN).

### <Stage>

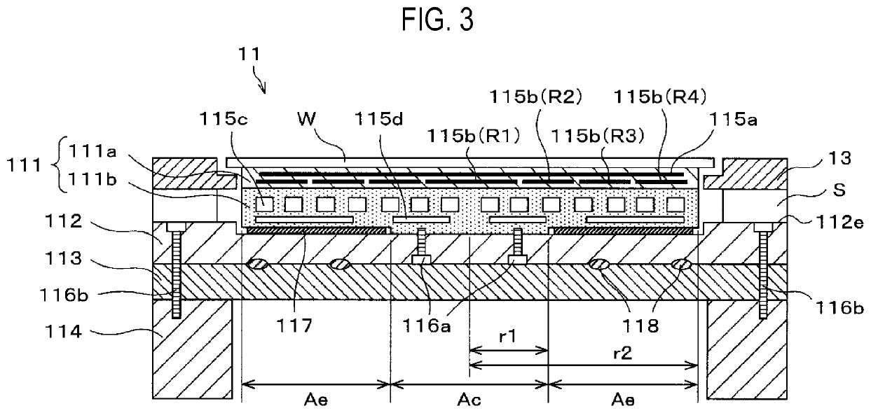

Next, a detailed configuration of the above-mentioned stage 2 will be described. FIG. 3 is a vertical cross-sectional view schematically illustrating an outline of the configuration of the stage 11.

As illustrated in FIG. 3, the stage 11 according to the present embodiment has a configuration in which the electrostatic chuck 111, the absorption plate 112, and the support plate 113 are concentrically stacked sequentially from above.

The electrostatic chuck 111 has a placement portion 111a having, on the top surface thereof, a substrate support surface on which the substrate W is electrostatically attracted and placed, and a base portion 111b configured to support the placement portion 111a from below. The placement portion 111a is made of, for example, ceramic or the like. The base portion 111b is made of, for example, aluminum or the like. In addition, each of the placement portion 111a and the base portion 111b are formed, for example, in a substantially disk-like shape having a diameter that is substantially the same as that of the substrate W or smaller than that of the substrate W.

An electrode 115a is provided inside the placement portion 111a. A DC power supply (not illustrated) is connected to the electrode 115a via, for example, a switch. In the placement portion 111a, it is possible to attractively hold the substrate W on the substrate support surface by virtue of a Coulomb force generated by applying a DC voltage from the DC power supply to the electrode 115a.

A heater 115b, which is a heating element, is provided below the electrode 115a. A heater power supply (not illustrated) is connected to the heater 115b. The stage 11 and the substrate W placed on the stage 11 are heated to a desired temperature by a voltage applied from the heater power supply. Further, in the present embodiment, a total of four heaters 115b are provided so as to respectively extend in a central region R1 of the stage 11 and a plurality of concentric annular regions R2, R3, and R4 surrounding the central region R1 such that the temperature of each of the regions R1 to R4 can be controlled independently of one another.

The number and shapes of the regions that are independently heated by the plurality of heaters 115b are not limited to this embodiment, and may be arbitrarily determined.

A coolant flow path 115c is formed inside the base portion 111b and below the heaters 115b. A chiller unit (not illustrated) is connected to the coolant flow path 115c. The stage 11 and the substrate W placed on the stage 11 are cooled down to a desired temperature by circulating a coolant (e.g., cooling water) supplied from the chiller unit in the coolant flow path.

In addition, the stage 11 is provided with a gas flow path 115d configured to supply a heat transfer gas (backside gas) such as a helium gas to a rear surface of the substrate W placed on the substrate support surface. A gas source (not illustrated) is connected to the gas flow path 115d. Thus, it is possible to control the substrate W placed on the stage 11 to a desired temperature using the heat transfer gas supplied from the gas source. In the example of FIG. 3, only a portion of the gas flow path 115d, that is, the gas flow path 115d in the base portion 111b is illustrated.

The absorption plate 112 as an absorption member has a substantially disk-like shape having a diameter larger than that of the electrostatic chuck 111. The absorption plate 112 is made of, for example, aluminum or the like. In the following description, an annular region of the absorption plate 112 exposed from the electrostatic chuck 111 in a plan view, that is, a region of the absorption plate 112 having a diameter larger than that of the electrostatic chuck 111 may be referred to as an “outer edge portion” of the absorption plate 112.

At an interface between the electrostatic chuck 111 and the absorption plate 112, a connection region Ac, in which the electrostatic chuck 111 and the absorption plate 112 are interconnected is formed in the central portion, and a separation region Ae, in which the electrostatic chuck 111 and the absorption plate 112 are spaced apart from each other, is formed on the outer-edge side of the connection region Ac.

The connection region Ac is formed by screwing, for example, fasteners 116a, such as bolt screws, from the side of the absorption plate 112 toward the electrostatic chuck 111 with respect to a convex portion that is formed as the central portion of the bottom surface of the base portion 111b of the electrostatic chuck 111 protrudes. That is, the electrostatic chuck 111 and the absorption plate 112 are fastened in the state of being in contact with each other in the connection region Ac.

Here, the size of the connection region Ac formed at the interface between the electrostatic chuck 111 and the absorption plate 112 is preferably, for example, 20% to 50% of the size of the electrostatic chuck 111. In other words, when the electrostatic chuck 111 and the absorption plate 112 are formed in a substantially disk-like shape as in the present embodiment, a radius r1 of the convex portion formed on the bottom surface of the electrostatic chuck 111 (a radius of the contact surface between the electrostatic chuck 111 and the absorption plate 112) is preferably 20% to 50% of a radius r2 of the electrostatic chuck 111. When the radius r1 is less than 20% of the radius r2, the connection region Ac is too small. Thus, the outer peripheral portion of the electrostatic chuck 111 may be bent downward due to its own weight, and the substrate support surface may have a convex shape. Meanwhile, when the radius r1 exceeds 50% of the radius r2, the connection region Ac is too large. Thus, the absorption plate 112 may not be able to exert the function to be described later. More specifically, when the absorption plate 112 is made of an aluminum disk as in the present embodiment, the radius of the connection region Ac is preferably ⅓ of the radius of the electrostatic chuck 111. When the connection region Ac is in such a range, it is possible for the absorption plate 112 to fully exert the function thereof while suppressing the deformation of the electrostatic chuck 111 due to its own weight.

In the present embodiment, as described above, the connection region Ac is formed by forming a convex portion on the bottom surface of the electrostatic chuck 111, and screwing the fasteners 116a to the convex portion. However, the method of forming the connection region Ac is not limited thereto. For example, in the above example, the convex portion is formed on the bottom surface of the electrostatic chuck 111, but the convex portion may be formed on the top surface of the absorption plate 112. In addition, for example, in the above example, the convex portion is formed on the electrostatic chuck 111 or the absorption plate 112 as described above, but instead of forming the convex portion, a plate for forming a connection region may be interposed at the interface. For example, in the above-described example, the electrostatic chuck 111 and the absorption plate 112 are fastened using the fasteners 116a, but the electrostatic chuck 111 and the absorption plate 112 may be fixed to each other using an adhesive or the like.

The separation region Ae is formed since the electrostatic chuck 111 and the absorption plate 112 are spaced apart from each other on the outer-edge side of the convex portion forming the connection region Ac. In other words, by interposing a convex portion forming the connection region Ac at the interface between the electrostatic chuck 111 and the absorption plate 112, the electrostatic chuck 111 and the absorption plate 112 are not in contact with each other on the outer-edge side of the convex portion so as to form a gap, whereby the separation region Ae is formed.

In the separation region Ae, since the gap is formed at the interface between the electrostatic chuck 111 and the absorption plate 112, the electrostatic chuck 111 and the absorption plate 112 are isolated from each other. As a result, for example, even when the absorption plate 112 or the support plate 113 to be described later is deformed convexly, the occurrence of the convex deformation in the electrostatic chuck 111 is suppressed. That is, the convex deformation generated on the stage 11 is absorbed by the absorption plate 112.

The gap forming the separation region Ae may be filled with an elastic body 117 (e.g., silicon or rubber) as a filler.

In addition, the top surface of the outer edge portion of the absorption plate 112 forms an edge ring placement portion 112e on which the edge ring 13 is placed. The edge ring 13 is placed on the edge ring placement portion 112e via a spacer member S so as to be in a concentric relationship with the electrostatic chuck 111.

The support plate 113 as a base has a substantially disk-like shape having substantially the same diameter as the absorption plate 112. The support plate 113 is made of, for example, aluminum or ceramic, and functions as a lower electrode in the plasma processing system 1. The absorption plate 112 and the support plate 113 are connected to each other at the outer edge portion of the absorption plate 112 by screwing fasteners 116b such as bolt screws from the side of the absorption plate 112 toward the support plate 113.

In addition, the fasteners 116b screwed from the side of the absorption plate 112 toward the support plate 113 penetrate the support plate 113, and are screwed to the substantial cylindrical placement base 114 arranged below the support plate 113. As a result, the support plate 113 (the stage 11) is fixed to the bottom surface of the plasma processing chamber 10 through the placement base 114.

The inside of the placement base 114 to which the stage 11 is fastened, that is, the lower portion of the stage 11 is set to a normal pressure atmosphere. Therefore, inside the stage 11, for example, at the interface between the absorption plate 112 and the support plate 113, as illustrated in FIG. 3, an O-ring 118 is preferably arranged so as to ensure airtightness between the normal pressure atmosphere below the support plate 113 and the plasma processing space 10s.

Although various exemplary embodiments have been described above, the present disclosure is not limited to the exemplary embodiments described above, and various omissions, substitutions, and changes may be made. In addition, elements in different embodiments may be combined to form other embodiments.

### Action and Effect of Stage According to the Present Embodiment

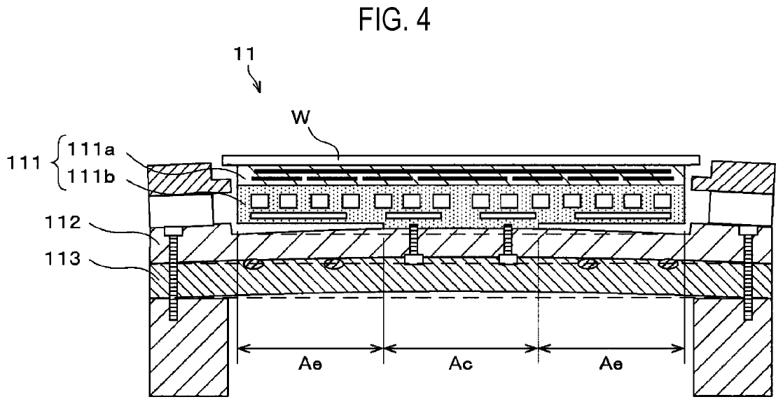

According to the stage 11 of the present embodiment, the separation region Ae is formed at the interface between the electrostatic chuck 111 and the absorption plate 112, and thus the electrostatic chuck 111 and the absorption plate 112 are isolated from each other. As a result, even when a convex deformation is generated in the stage 11 by, for example, stress acting due to the fastening of the fasteners 116b, the pushing force acting by the O-ring 118, and an atmospheric pressure acting from the normal pressure atmosphere below the stage 11 as illustrated in FIG. 1, the convex deformation is absorbed by the absorption plate 112. Specifically, as illustrated in FIG. 4, even when the absorption plate 112 and the support plate 113 are convexly deformed, the convex deformation of the electrostatic chuck 111 isolated from the absorption plate 112 by the separation region Ae is suppressed. As a result, it is possible to cause the substrate W to be uniformly attracted to and held on to the entire surface of the substrate support surface of the electrostatic chuck 111.

Since it is possible to cause the substrate W to be uniformly attracted to and held on to the entire surface of the electrostatic chuck 111 in this way, it is possible to improve the uniformity of the in-plane temperature of the substrate W in the plasma processing, and to reduce the amount of leakage of the heat transfer gas (the backside gas) supplied to the rear surface of the substrate W. That is, it is possible to appropriately perform the plasma processing on the substrate W.

In addition, according to the present embodiment, it is also possible to absorb the tolerance between components in the stage 11 by the absorption plate 112 provided between the electrostatic chuck 111 and the support plate 113. Therefore, it is possible to suppress an individual difference and a variation in temperature of the stage 11 in the plasma processing, and thus to more appropriately perform the plasma processing on the substrate W.

In addition, according to the present embodiment, since the absorption plate 112 absorbs the convex deformation generated on the stage 11 in this way, it is not necessary to perform concave processing in advance on the substrate support surface of the electrostatic chuck 111 as in the conventional case. In this way, since it is possible to bring the substrate W and the substrate support surface of the electrostatic chuck 111 into uniform contact with each other without performing the concave processing, it is possible to appropriately suppress a decrease in withstand voltage margin when RF is applied to the electrostatic chuck 111.

In addition, according to the present embodiment, it is not necessary to improve the attraction followability of the substrate W with respect to the substrate support surface by increasing an attraction voltage as in the conventional case. Therefore, since the generation of particles due to the rubbing between the substrate W and the substrate support surface of the electrostatic chuck 111 is suppressed, it is possible to more appropriately perform the plasma processing on the substrate W.

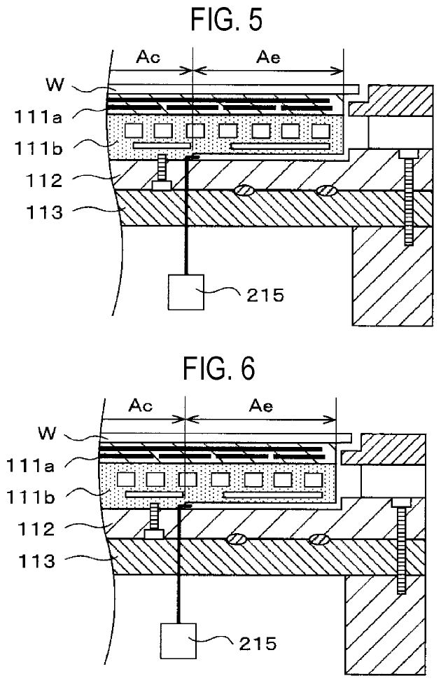

In the embodiments described above, as illustrated in FIG. 3, by filling the separation region Ae with an elastic body such as silicon or rubber, the electrostatic chuck 111 and the absorption plate 112 are isolated from each other, and the occurrence of abnormal discharge on the stage 11 is suppressed. However, the filler filling the separation region Ae is not limited to the elastic body, and as illustrated in FIG. 5, a gas source 215 capable of supplying an inert gas may be connected to the separation region Ae so as to use the inert gas as the filler. Even when the inert gas is used as the filler in this way, it is possible to implement the isolation between the electrostatic chuck 111 and the absorption plate 112 and to suppress the occurrence of abnormal discharge on the stage 11.

In addition, when the inert gas is supplied to the separation region Ae as the filler in this way, as illustrated in FIG. 6, a partition member 215a may be provided so as to divide the separation region Ae into a plurality of compartments Z (in the illustrated example, three compartments Z1 to Z in the radial direction), and the inert gas may be independently supplied to each compartment Z. In such a case, it is desirable to provide a pressure adjustment unit 215b configured to independently control the pressure in each compartment Z. As the partition member 215a, a member capable of ensuring airtightness between the respective compartments Z (e.g., an O-ring or an X-ring) may be used, but it is more desirable to select a member having a small reaction force to the electrostatic chuck 111 or the absorption plate 112 (e.g., an X-ring).

By dividing the separation region Ae into the plurality of compartments Z in this way and implementing the configuration in which the inert gas can be independently supplied to each compartment Z, it is possible to control a surface profile of the substrate support surface of the electrostatic chuck 111 for each compartment Z. In other words, for example, even when the flatness of the stage 11 and the substrate W placed on the stage 11 is deteriorated due to various conditions, it is possible to adjust the flatness of the substrate support surface and the placed substrate W by controlling the supply pressure of the inert gas for each compartment Z. This makes it easy to bring the substrate W and the substrate support surface of the electrostatic chuck 111 into uniform contact with each other, and thus it is possible to more appropriately perform the plasma processing on the substrate W.

The supply amount of the inert gas for each compartment Z may be controlled based on, for example, a variation in the flatness of the substrate support surface of the stage 11 or the placed substrate W detected by a displacement gauge or the like in the plasma processing. However, the method for controlling the supply amount of the inert gas is not limited thereto, and it is possible to control the supply amount of the inert gas through any method. Specifically, for example, the in-plane temperature distribution of the substrate W placed on the stage 11 may be measured, and the supply amount of the inert gas (the surface profile of the substrate support surface) may be controlled based on the temperature distribution. In addition, for example, the leakage amount of the heat transfer gas (the backside gas) supplied to the rear surface of the substrate W placed on the stage 11 is detected, and the supply amount of the inert gas (the surface profile of the substrate support surface) may be controlled based on the distribution of the leakage amount.

Furthermore, the number and shapes of the compartments Z formed by the partition member 215a may be arbitrarily determined. By appropriately setting the number and shapes of the compartments Z, it is possible to more appropriately improve the surface profile (flatness) of the substrate support surface. In this case, by setting the number and shapes of the compartments Z to be the same as the number and shapes of the regions in which the temperature is independently controlled by the heater 115b (annular regions R2 to R4 in the present embodiment), it is possible to adjust the temperature and flatness for each compartment Z (for each region R), and thus to more appropriately perform the plasma processing on the substrate W.

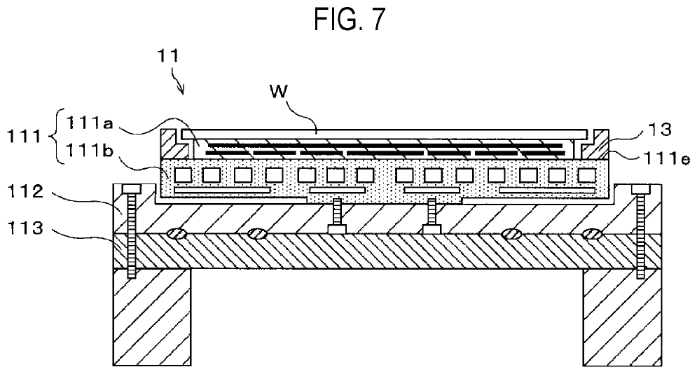

In the embodiments described above, the edge ring 13 is placed on the edge ring placement portion 112e, which is formed on the outer edge portion of the absorption plate 112, through the spacer member S, but the formation position of the edge ring placement portion 112e is not limited to these embodiments. For example, as illustrated in FIG. 7, the radius of the base portion 111b of the electrostatic chuck 111 may be larger than that of the placement portion 111a, and the outer edge portion of the base portion 111b may be configured as the edge ring placement portion 111e.

It should be noted that the embodiments and modifications disclosed herein are exemplary in all respects and are not restrictive. The above-described embodiments may be omitted, replaced or modified in various forms without departing from the scope and spirit of the appended claims.

For example, the plasma processing system of the embodiments described above has a capacitively coupled plasma processing apparatus, but the plasma processing system to which the present disclosure is applied is not limited thereto. For example, the plasma processing system may have an inductively coupled plasma processing apparatus. Regardless of the system configuration of the plasma processing system, it is possible to provide the above-mentioned effects using the stage of the embodiments described above.

Moreover, for example, in the embodiments described above, the stage according to the technique of the present disclosure is provided inside the plasma processing apparatus, but the type of the substrate processing apparatus in which the stage is provided is not limited thereto. For example, the stage according to the technique of the present disclosure is appropriately applicable to an arbitrary substrate processing apparatus, such as a vacuum processing apparatus or a grinding apparatus, in which convex deformation may occur on the stage or a placed substrate.

According to the present disclosure, in a stage provided with a substrate support surface, it is possible to improve the flatness of the substrate support surface.

What is claimed is:

1. A substrate support, comprising:
an electrostatic chuck including a substrate support surface on which the substrate is supported;
a base configured to support the electrostatic chuck; and
an absorption member arranged between the electrostatic chuck and the base and including an outer edge portion fastened to the base via a fastener,
wherein, between the electrostatic chuck and the absorption member, a connection region, in which the electrostatic chuck and the absorption member are interconnected in a central portion of the electrostatic chuck, and a separation region, in which the electrostatic chuck and the absorption member are spaced apart from each other on an outer-edge side of the connection region, are formed.

2. The substrate support of claim 1, wherein the electrostatic chuck and the absorption member have a cylindrical shape,
the connection region is in a circular shape in a concentric relationship with the electrostatic chuck in a plan view, and
the connection region has a radius that is 20% to 50% of a radius of the electrostatic chuck.

3. The substrate support of claim 2, wherein the absorption member is made of aluminum, and
the radius of the circular shape forming the connection region is ⅓ of the radius of the electrostatic chuck.

4. The substrate support of claim 1, wherein the separation region is filled with an elastic material.

5. The substrate support of claim 1, further comprising:
an inert gas supply part configured to supply an inert gas to the separation region.

6. The substrate support of claim 5, further comprising:
a partition member configured to divide the separation region into a plurality of compartments,
wherein the inert gas supply part is configured to be capable of independently supplying the inert gas to each of the plurality of compartments.

7. The substrate support of claim 6, wherein the inert gas supply part includes a pressure adjustment unit configured to be capable of independently adjusting a supply pressure of the inert gas supplied to each of the plurality of compartments.

8. The substrate support of claim 1, further comprising:
an edge ring support surface arranged around the substrate support surface.

9. A substrate processing apparatus for processing a substrate, comprising:
a processing chamber configured to process the substrate therein; and
the substrate support of claim 1 arranged inside the processing chamber.

10. The substrate processing apparatus of claim 9, further comprising:
a heat transfer gas supply unit configured to supply a heat transfer gas to a gap between the substrate support surface and the substrate supported the substrate support surface.

11. A substrate processing method of processing a substrate in a substrate processing apparatus,
wherein the substrate processing apparatus includes: a processing chamber configured to process the substrate therein; and a substrate support arranged inside the processing chamber, and
the substrate support includes:
an electrostatic chuck including a substrate support surface which the substrate is supported;
a base configured to support the electrostatic chuck;
an absorption member provided between the electrostatic chuck and the base, and including a central portion connected to the electrostatic chuck and an outer edge portion fastened to the base via a fastener;
an elastic body configured to divide a separation region, which is formed by separating the electrostatic chuck and the absorption member from each other on an outer-edge side of a connection portion between the electrostatic chuck and the absorption member, into a plurality of compartments;
an inert gas supply part configured to be capable of independently supplying an inert gas to the plurality of compartments; and
a pressure adjustment unit configured to be capable of independently adjusting a supply pressure of the inert gas supplied to each of the plurality of compartments,
the substrate processing method comprises:
adjusting the supply pressure of the inert gas to each of the plurality of compartments so as to change a flatness of the substrate support surface.

12. The substrate processing method of claim 11, wherein the supply pressure of the inert gas to each of the plurality of compartments is adjusted based on a surface temperature distribution of the substrate placed on the substrate support surface.

13. The substrate processing method of claim 12, wherein the substrate processing apparatus further comprises a heat transfer gas supply unit configured to supply a heat transfer gas to a gap between the substrate support surface of the substrate support and the substrate placed on the substrate support, and
the supply pressure of the inert gas to each of the plurality of compartments is adjusted based on an amount of the heat transfer gas leaking from the gap.

14. The substrate processing method of claim 12, wherein the substrate processing apparatus further comprises a heat transfer gas supply unit configured to supply a heat transfer gas to a gap between the substrate support surface of the substrate support and the substrate placed on the substrate support, and
the supply pressure of the inert gas to each of the plurality of compartments is adjusted based on an amount of the heat transfer gas leaking from the gap.

15. A substrate processing apparatus, comprising:
a processing chamber configured to process the substrate therein;
a substrate support arranged inside the processing chamber; and
a controller,
wherein the substrate support includes:
an electrostatic chuck including a substrate support surface which the substrate is supported;
a base configured to support the electrostatic chuck;
an absorption member provided between the electrostatic chuck and the base, and including a central portion connected to the electrostatic chuck and an outer edge portion fastened to the base via a fastener;
an elastic body configured to divide a separation region, which is formed by separating the electrostatic chuck and the absorption member from each other on an outer-edge side of a connection portion between the electrostatic chuck and the absorption member, into a plurality of compartments; and
an inert gas supply part configured to be capable of independently supplying an inert gas to the plurality of compartments,
wherein the controller is configured to adjust a supply pressure of the inert gas to each of the plurality of compartments according to a change in flatness of a surface of the substrate supported on the substrate support surface.
